(19) United States
(12) Patent Application Publication
(10) Pub. No.: US 2026/0180557 A1
(43) Pub. Date: Jun. 25, 2026

(54) Transposed Digital Filter Circuitry

(71) Applicant: Altera Corporation, San Jose, CA (US)

(72) Inventors: Martin Langhammer, Alderbury (GB); Volker Mauer, Princes Risborough (GB)

(21) Appl. No.: 18/988,356

(22) Filed: Dec. 19, 2024

(51) Int. Cl. H03H 17/02; H03H 17/00

(52) U.S. Cl. CPC H03H 17/02; H03H 2017/0081

(57) ABSTRACT

Integrated circuit devices and circuitry for digital filtering are provided. An integrated circuit device may include programmable logic circuitry and a digital signal processing (DSP) block embedded in the programmable logic circuitry having a plurality of hardened multipliers and registers and being configurable to implement a transposed finite impulse response (FIR) filter.

### BACKGROUND

This disclosure relates to circuitry to perform digital filtering using transposed filters, such as transposed finite impulse response (FIR) filters or hybrid transposed FIR filters.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Many integrated circuits include arithmetic circuit blocks to perform arithmetic operations such as addition and multiplication. For example, a digital signal processing (DSP) block may supplement programmable logic circuitry in a programmable logic device, such as a field programmable gate array (FPGA). Programmable logic circuitry and DSP blocks may be used to perform numerous different arithmetic functions. Finite impulse response (FIR) filters are one of the most used application areas for FPGA. A FIR filter may have a direct form or a transposed form. The transposed form may provide some advantages over a direct form. While the transposed form of a FIR filter may map well to single-multiplier DSP blocks, many embedded DSP blocks increasingly have a higher multiplier density.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of the integrated circuit device of FIG. 1;

FIG. 3 is a block diagram of a finite impulse response (FIR) filter having a direct form that may be implemented using digital signal processing (DSP) blocks of the integrated circuit device;

FIG. 4 is a block diagram of a FIR filter having a transposed form that may be implemented using DSP blocks of the integrated circuit device;

FIG. 5 is a block diagram of a DSP block implementing a direct form of a FIR filter;

FIG. 6 is a block diagram of a DSP block implementing a transposed form of a FIR filter;

FIG. 7 is a block diagram of a DSP block implementing a transposed form of a halfband FIR filter;

FIG. 8 is a dataflow of a direct form of a FIR filter implemented using embedded DSP blocks;

FIG. 9 is a dataflow of a hybrid transposed form of a FIR filter implemented using embedded DSP blocks;

FIG. 10 is a block diagram of a hybrid transposed FIR filter in which several four-multiplier DSP blocks are used to implement direct FIR filters that are connected to one another in a transposed manner;

FIG. 11 is a block diagram of a four-multiplier DSP block having circuitry to support implementing the hybrid transposed FIR filter of FIG. 10;

FIG. 12 is a block diagram of a hybrid transposed FIR filter in which several two-multiplier DSP blocks are used to implement direct FIR filters that are connected to one another in a transposed manner;

FIG. 13 is a block diagram of a hybrid multi-channel transposed FIR filter implemented using a hybrid transposed FIR filter and delayed groups of inputs;

FIG. 14 is a block diagram of tensor circuits of a DSP block that may be used to provide delay within the DSP block to support a hybrid multi-channel transposed FIR filter;

FIG. 15 is a block diagram illustrating the implementation of an extended delay to support a hybrid multi-channel transposed FIR filter using tensor circuits of a DSP block;

FIG. 16 is a block diagram of circuity to implement a generalized form of a hybrid multi-channel transposed FIR filter;

FIG. 17 is a block diagram of an input sequence of data through a two-channel hybrid filter implemented using DSP blocks;

FIG. 18 is a block diagram of an intermediate sequence of data through a two-channel hybrid filter implemented using DSP blocks;

FIG. 19 is a block diagram of an output sequence of data through a two-channel hybrid filter implemented using DSP blocks; and

FIG. 20 is a block diagram of a data processing system that may incorporate an integrated circuit device implementing a filter of this disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

Many integrated circuits, such as programmable logic devices, include DSP blocks. DSP blocks include “hardened” circuits that are specialized to efficiently perform certain mathematical operations. This is in contrast to “soft logic” circuits that may be formed by programming programmable logic circuitry, but which may not be as efficient. One desirable use case for DSP blocks is digital filtering. Many digital filters, such as finite impulse response (FIR) filters, may take a number of different forms. A direct form often involves pipelining input data through a chain of delay registers, before multiplying the input data to respective coefficients and adding the results. A transposed form of a FIR filter is functionally equivalent to the direct form of the FIR filter, but the transposed form applies the delays into an output chain rather than the input chain. A hybrid transposed FIR filter may include some portions that take a direct form that are connected together in a transposed form. This disclosure includes circuitry and techniques to efficiently implement FIR filters using DSP circuitry, such as embedded DSP blocks of a field programmable gate array (FPGA).

Before continuing, it should be noted that this disclosure describes a number of specific examples of transposed and hybrid transposed filters that may be implemented using embedded DSP blocks of an FPGA. Any suitable bit depth (e.g., 2-bit, 3-bit, 4-bit, 6-bit, 8-bit, 10-bit, 16-bit, 32-bit, 64-bit, 128-bit, or higher or lower), number of taps (e.g., 2 taps, 3 taps, 4 taps, 8 taps, 16 taps, 20 taps, 40 taps, 80 taps, or more or fewer), channels (e.g., 1 channel, 2 channels, 3 channels, 4 channels, 8 channels, or more or fewer), and coefficients may be used. Indeed, multiplier and adder precisions may also take any suitable values. In any single filter, the multipliers and adders may be the same or different combinations of precisions may be used. The circuitry of this disclosure is provided by way of example and is not meant to be exhaustive.

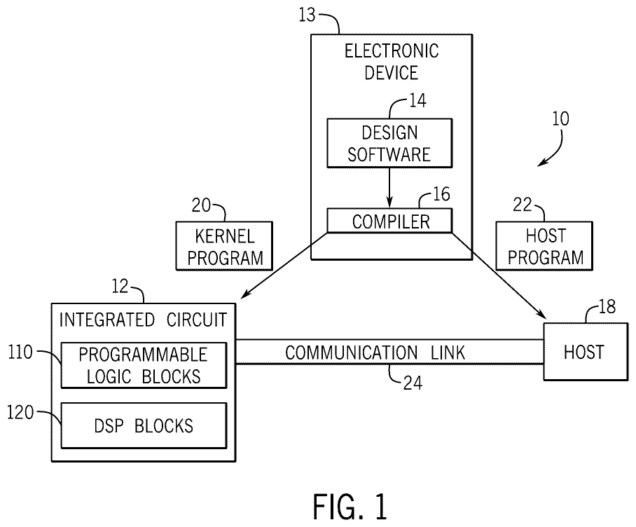

FIG. 1 illustrates a block diagram of a system 10 that may be used to implement the filtering systems and methods of this disclosure on an integrated circuit system 12 (e.g., a single monolithic integrated circuit or a multi-die system of integrated circuits). A designer may desire to implement a system design to perform filtering operations on the integrated circuit system 12 (e.g., a programmable logic device such as a field-programmable gate array (FPGA) or an application-specific integrated circuit (ASIC) that includes programmable logic circuitry). The integrated circuit system 12 may include a single integrated circuit, multiple integrated circuits in a package, or multiple integrated circuits in multiple packages communicating remotely (e.g., via wires or traces) and may be referred to as an integrated circuit device whether formed from a single integrated circuit or multiple integrated circuits in a package. In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In a configuration mode of the integrated circuit device 12, a designer may use an electronic device 13 (e.g., a computer including a data processing system having a processor and memory or storage) to implement high-level designs (e.g., a system user design) using design software 14 (e.g., executable instructions stored in a tangible, non-transitory, computer-readable medium such as the memory or storage of the electronic device 13), such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit system 12. The host 18 may receive a host program 22 that may control or be implemented by the kernel programs 20. To implement the host program 22, the host 18 may communicate instructions from the host program 22 to the integrated circuit system 12 via a communications link 24 that may include, for example, direct memory access (DMA) communications or peripheral component interconnect express (PCIe) communications. In some embodiments, the kernel programs 20 and the host 18 may configure programmable logic blocks (e.g., LABs 110) on the integrated circuit system 12. The programmable logic blocks (e.g., LABs 110) may include circuitry and/or other logic elements and may be configurable to implement a variety of functions in combination with digital signal processing (DSP) blocks 120.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

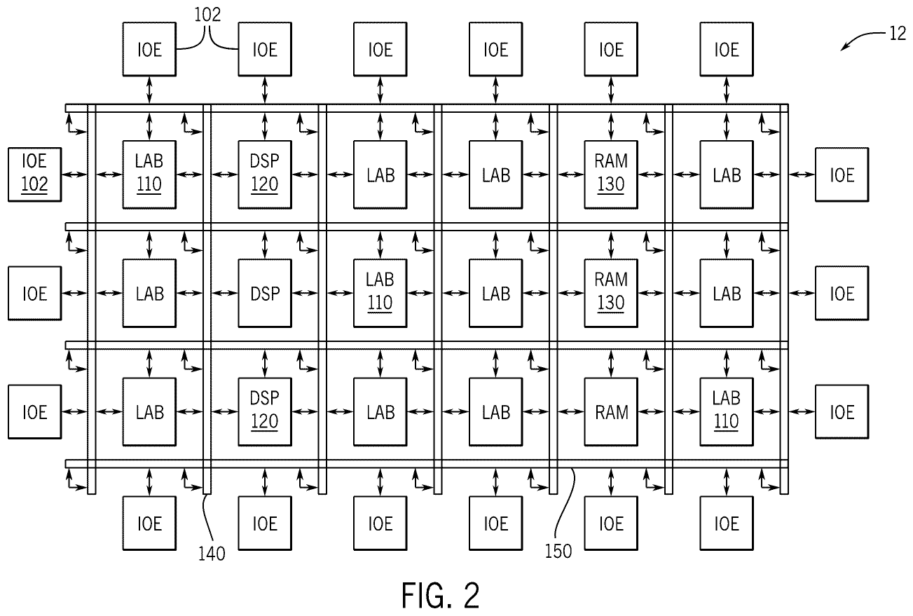

An illustrative embodiment of a programmable integrated circuit system 12 such as a programmable logic device (PLD) (e.g., a field programmable gate array (FPGA) device) that may be configured to implement a circuit design (also sometimes referred to as a system design) is shown in FIG. 2. The integrated circuit system 12 (e.g., a field-programmable gate array (FPGA) integrated circuit device) may include a two-dimensional array of functional blocks sometimes referred to as programmable logic blocks (e.g., also referred to as logic array blocks (LABs) 110 or configurable logic blocks (CLBs)) that may include some number of adaptive logic modules (ALMs) that may be programmed to behave as particular logic circuitry. The integrated circuit system 12 may also include other functional blocks, such as embedded digital signal processing (DSP) blocks 120 and embedded random-access memory (RAM) blocks 130. Functional blocks such as LABs 110 may include smaller programmable regions (e.g., logic elements, configurable logic blocks, or adaptive logic modules) that receive input signals and perform custom functions on the input signals to produce output signals. LABs 110 may also be grouped into larger programmable regions, sometimes referred to as logic sectors, that are individually managed and configured by corresponding logic sector managers. The grouping of the programmable logic resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy.

Programmable logic circuitry of the integrated circuit system 12 may be controlled by programmable memory elements sometimes referred to as configuration random access memory (CRAM). Memory elements may be loaded with configuration data (also called programming data or a configuration bitstream) using input-output elements (IOEs) 102. Once loaded, the memory elements each provide a corresponding static control signal that controls the operation of an associated functional block (e.g., LABs 110, DSP blocks 120, RAM 130, or IOEs 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory (ROM) memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. The integrated circuit system 12 (e.g., as a programmable logic device (PLD)) may be configured to implement a custom circuit design. For example, the configuration RAM may be programmed such that LABs 110, DSP blocks 120, and RAM 130, programmable interconnect circuitry (e.g., vertical channels 140 and horizontal channels 150), and the input-output elements 102 form the circuit design implementation.

In addition, the programmable logic device may have input-output elements (IOEs) 102 for driving signals off the integrated circuit system 12 and for receiving signals from other devices. Input-output elements 102 may include parallel input-output circuitry, serial data transceiver circuitry, differential receiver and transmitter circuitry, or other circuitry used to connect one integrated circuit to another integrated circuit.

The integrated circuit system 12 may also include programmable interconnect circuitry in the form of vertical routing channels 140 (i.e., interconnects formed along a vertical axis of the integrated circuit system 12) and horizontal routing channels 150 (i.e., interconnects formed along a horizontal axis of the integrated circuit system 12), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 2, are intended to be included within the scope of the present disclosure. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit system 12, fractional global wires such as wires that span part of the integrated circuit system 12, staggered wires of a particular length, smaller local wires, or any other suitable interconnection resource arrangement.

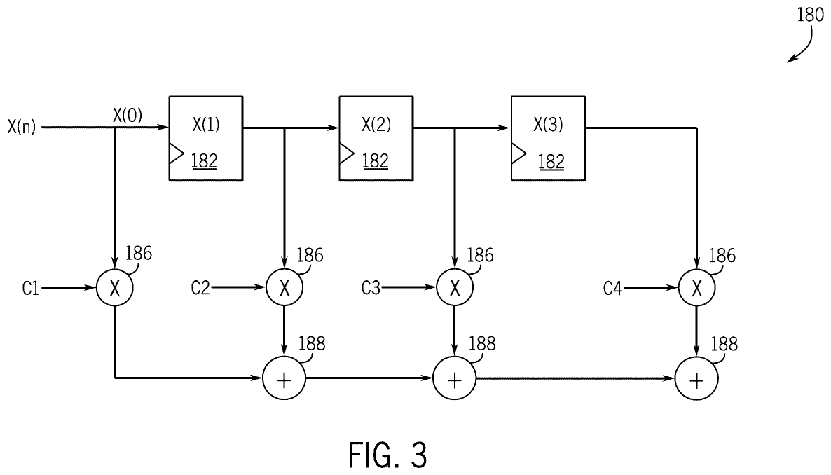

The integrated circuit device 12 may be programmed to perform a wide variety of operations. One example shown in FIG. 3 is finite impulse response (FIR) filtering. For example, the integrated circuit device 12 may be programmed to implement a FIR filter 180. The FIR filter 180 of FIG. 3 has a direct form. In the example of FIG. 3, the FIR filter 180 receives an input signal x(n). The FIR filter 180 illustrated in FIG. 3 has four taps, to a point x(3) of the signal x(n) when the first point in the x(n) signals is x(0). The x(n) signal traverses registers 182 along an input chain that provide the input signal at the tap points into multipliers 186, which multiply the respective input signal by a coefficient C1, C2, C3, or C4. The partial results are summed together in adders 188 (sometimes referred to as reduction circuitry) to obtain the result of the filter 180. The adders 188 may be separate addition circuits or a single larger summation circuit.

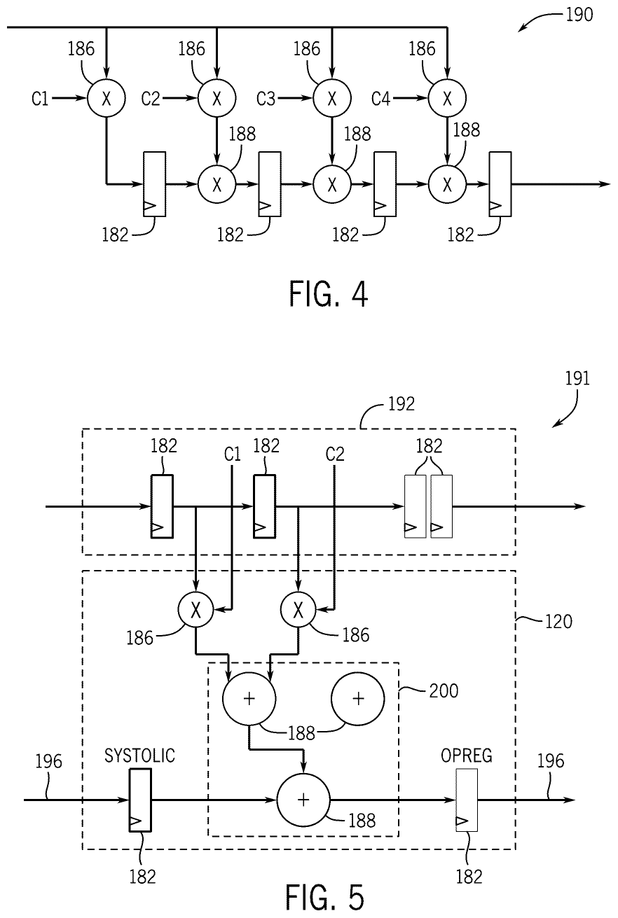

FIG. 4 illustrates a transposed FIR filter 190, which produces the same results as the FIR filter 180 of FIG. 3, but which has a transposed form. In transposed form, the input data is not delayed but the output data is. Thus, input data is provided without delay to the multipliers 186. The resulting products are added in adders 188 to output data that is delayed. To this end, the transposed FIR filter 190 includes an output chain of registers 182 (in contrast to the input chain as in the direct FIR filter 180 of FIG. 3). The result of the transposed filter FIR 190 of FIG. 4 is the same as the result of the direct FIR filter 180 of FIG. 3, but routing the input data to the transposed filter FIR 190 of FIG. 4 may be simpler.

FIG. 5 illustrates a way to implement a two-tap direct FIR filter 191 using circuitry of a DSP block 120. The two-tap direct FIR filter 191 shown in FIG. 5 may be chained to other DSP blocks 120 to produce a multi-tap direct FIR filter. The two-tap direct FIR filter 191 is formed using an input data chain 192 of registers 182 and a DSP block 120. Multipliers 186 of the DSP block 120 may receive input data via the input data chain 192 of registers 182. The input data chain 192 may include one registers 182 for each tap, as well as additional registers 182 to provide additional delay to balance the input data as it travels from one two-tap direct FIR filter 191 (when used to form a larger multi-tap direct FIR filter). Note that additional registers 182 may be included in the input data chain 192 of registers 182 provided the results are balanced (e.g., two registers 182 rather than one register 182 may be between the first tap and the second tap, provided that there is a corresponding delay register 182 added after the multiplier 186 corresponding to the first tap; three registers 182 may be between the first tap and the second tap and there may be two corresponding delay registers 182 added after the multiplier 186 corresponding to the first tap).

The DSP block 120 may include an input systolic (“systolic”) register 182 and an output register (“opreg”) register 182. The input systolic (“systolic”) register 182 may receive filter results from a previous DSP block 120 (not shown) from a direct path 196. The direct path 196 may connect each adjacent DSP block 120 in a column of DSP blocks 120 of the integrated circuit device to enable the filter results to traverse directly from one DSP block 120 to another DSP block 120 without using additional programmable routing or programmable logic block resources. When results from a first DSP block 120 are passed to a second DSP block 120, the results may traverse the output register (“opreg”) register 182 of the first DSP block 120 and the input systolic (“systolic”) register 182 of the second DSP block 120. Therefore, the input data chain 192 may include two additional registers 182 to provide a corresponding balancing delay. More or fewer delay stages may be used in the DSP block 120 and the input data chain 192, provided the amount of delay across the DSP block 120 and the input data chain 192 remains balanced. In the example of FIG. 5, the DSP block 120 may use adders 188 that compose larger floating-point addition circuitry 200 to implement addition for the two-tap direct FIR filter 191.

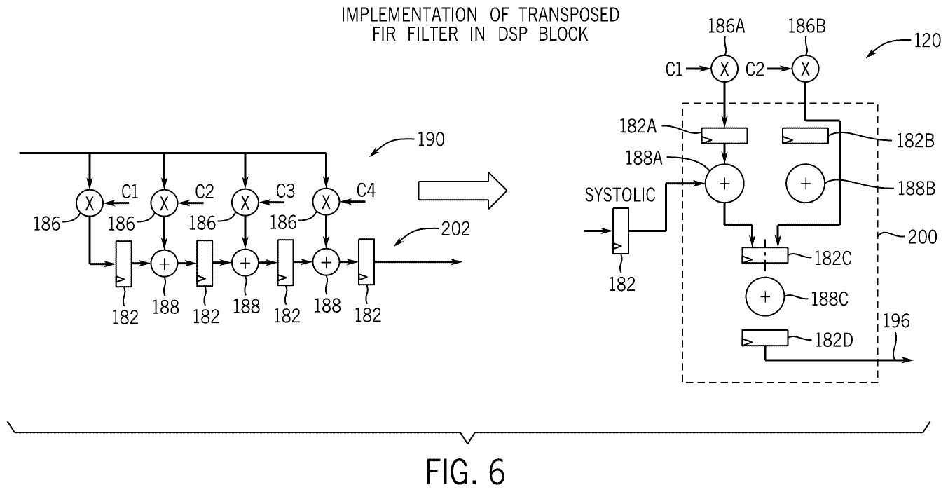

DSP blocks 120 may also be used to implement transposed FIR filters, such as the transposed FIR filter 190. An example shown in FIG. 6 illustrates the use of one two-multiplier DSP block 120 to implement half of the transposed FIR filter 190. The entire transposed FIR filter 190 may be formed by chaining two DSP blocks 120 in the configuration of FIG. 6.

The lefthand side of FIG. 6 represents the four-tap transposed FIR filter 190. There is no input signal delay chain, simplifying the routing of the input data into the transposed FIR filter 190. Instead, the input data enters all of the multipliers 186 to be multiplied by coefficients c1, c2, c3, and c4 at once and then the results are delayed by an output delay chain 202 of registers 182, which pass the results obtained by adding the product of the multipliers 186 with the previous filter results in adders 188.

The righthand side of FIG. 6 represents one implementation of the first two taps of the four-tap transposed FIR filter 190 using one DSP block 120. The full four-tap transposed FIR filter 190 may be implemented by connecting two DSP blocks 120 in the configuration shown in FIG. 6. Additionally or alternatively, the DSP block 120 of FIG. 6 may be multiplexed to operate on the first two taps in one cycle, then the next two taps in another cycle, and so forth, using any suitable programmable routing (e.g., via FPGA programmable logic circuitry). As shown in FIG. 6, a first multiplier 186A may provide its product (e.g., input data multiplied by the first coefficient c1) into a register 182A found in the floating-point addition circuitry 200. After one cycle of delay, this value in the register 182A may be added, in an adder 188A, to a result from a previous DSP block 120 (if the DSP block 120 shown in FIG. 6 is part of a multi-tap chain) by way of a systolic register (“systolic”) register 182. The output of the adder 188A may enter a register 182B. Meanwhile, the product of a second multiplier 186B (e.g., the input data multiplied by the second coefficient c2) may bypass a corresponding register 182B and an adder 188B and go directly to the register 182C. Note that the register 182C may be large enough to hold both of these values. For example, the values may be 32-bit values and at least the register 182C may hold 64 bits. Additionally or alternatively, two different registers 182 may be used. These values stored in the register 182C may be added together in an adder 188C and the result delayed by a register 182D. Additionally or alternatively, the result of the adder 188C may bypass the register 182D and enter an output register (“opreg”) register 182 (not shown in FIG. 6).

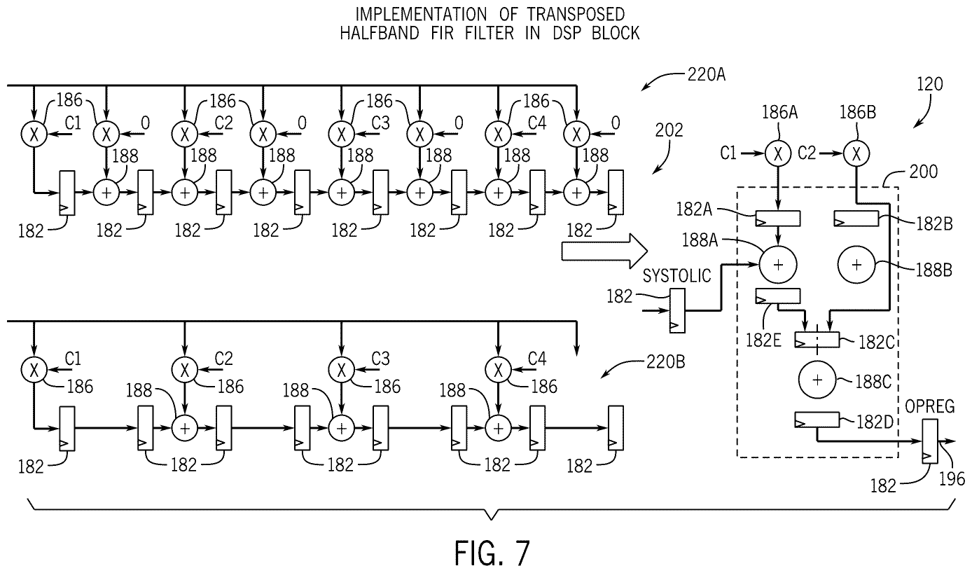

Another form of a FIR filter is a halfband FIR filter, in which every other multiplication is a multiply-by-0 operation. A halfband FIR filter represents one type of sparse FIR filter; other sparse filters that have multiply-by-0 operations other than the halfband FIR filter may be implemented using the techniques of this disclosure provided the DSP blocks 120 have sufficient delay registers 182. FIG. 7 illustrates one manner of implementing a transposed halfband FIR filter using the DSP blocks 120. The lefthand side of FIG. 7 schematically illustrates a transposed halfband FIR filter 220A, which may be logically condensed into a transposed halfband FIR filter 220B. In particular, the transposed halfband FIR filter 220A includes a number of multiply-by-0 operations where certain multipliers 186 would be used to multiply by 0, always producing a product of 0 that would be added by the adders 188 to the previous result along an output delay chain 202 of registers 182. The transposed halfband FIR filter 220B is logically equivalent to the halfband FIR filter 220A but uses less circuitry. In particular, the multipliers 186 and adders 188 corresponding to multiply-by-0 operations in the transposed halfband FIR filter 220A may simply not be used in the transposed halfband FIR filter 220B. To account for the delay involved in the multiply-by-0 operations of the transposed halfband FIR filter 220A, the transposed halfband FIR filter 220B includes the same number and position of registers 182 in its output delay chain 202 of registers 182.

The righthand side of FIG. 7 represents one implementation of the first two taps of the transposed halfband FIR filter 220B using one DSP block 120. The full transposed halfband FIR filter 220B may be implemented by connecting two DSP blocks 120 in the configuration shown in FIG. 6. Additionally or alternatively, the DSP block 120 of FIG. 7 may be multiplexed to operate on the first two taps in one cycle, then the next two taps in another cycle, and so forth, using any suitable programmable routing (e.g., via FPGA programmable logic circuitry). In comparison to the transposed FIR filter 190 implemented in FIG. 6, to implement the transposed halfband FIR filter 220B as shown in FIG. 7, an additional register 182E may be used to provide one additional cycle of delay to account for one multiply-by-0 operation and the output of the DSP block 120 may be output through an output register (“opreg”) register 182 to account for another multiply-by-0 operation.

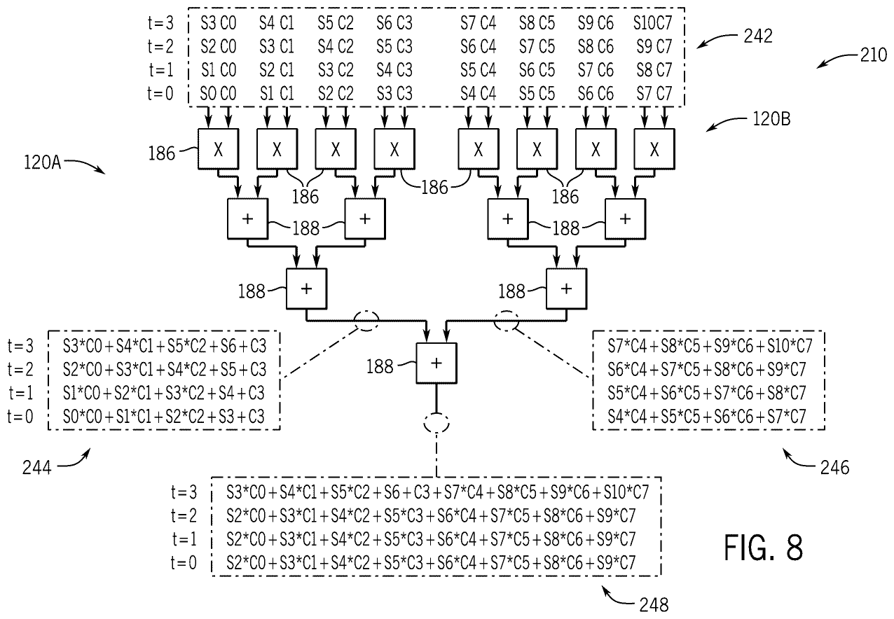

FIG. 8 is a dataflow diagram illustrating a dataflow through an 8-tap direct FIR filter 240 implemented using two four-tap DSP blocks 120A and 120B over four cycles t=0, t=1, t=2, and t=3. The DSP blocks 120A and 120B include four multipliers 186, the results of which are added together in adders 188. Input data signals and coefficients may be provided according to an input sequence 242 that may be implemented in programmable logic circuitry. The input data signals may be a stream of input data S0, S1, . . . S10, and so forth and the coefficients are C0, C1, . . . C7, and so forth. At each cycle, the input data shifts across into the DSP blocks 120A and 120B by one. Thus, at time t=0, the first multiplier 186 of the DSP block 120A multiplies input data S0 by coefficient C0; at time t=1, the first multiplier 186 of the DSP block 120A multiplies input data S1 by coefficient C0; at time t=2, the first multiplier 186 of the DSP block 120A multiplies input data S2 by coefficient C0; and at time t=3, the first multiplier 186 of the DSP block 120A multiplies input data S3 by coefficient C0. Similarly, at time t=0, the first multiplier 186 of the DSP block 120B multiplies input data S4 by coefficient C4; at time t=1, the first multiplier 186 of the DSP block 120B multiplies input data S5 by coefficient C4; at time t=2, the first multiplier 186 of the DSP block 120B multiplies input data S6 by coefficient C4; and at time t=3, the first multiplier 186 of the DSP block 120B multiplies input data S7 by coefficient C4. The input sequence 242 also provides the schedule for the rest of the multipliers 186 of the DSP blocks 120A and 120B.

The results of the DSP block 120A are shown in a first intermediate sequence 244 and the results of the DPS block 120B are shown in a second intermediate sequence 246. These may be added together in an adder 188 (e.g., located in the second DSP block 120B or implemented in soft logic of programmable logic circuitry) to produce an output sequence 248.

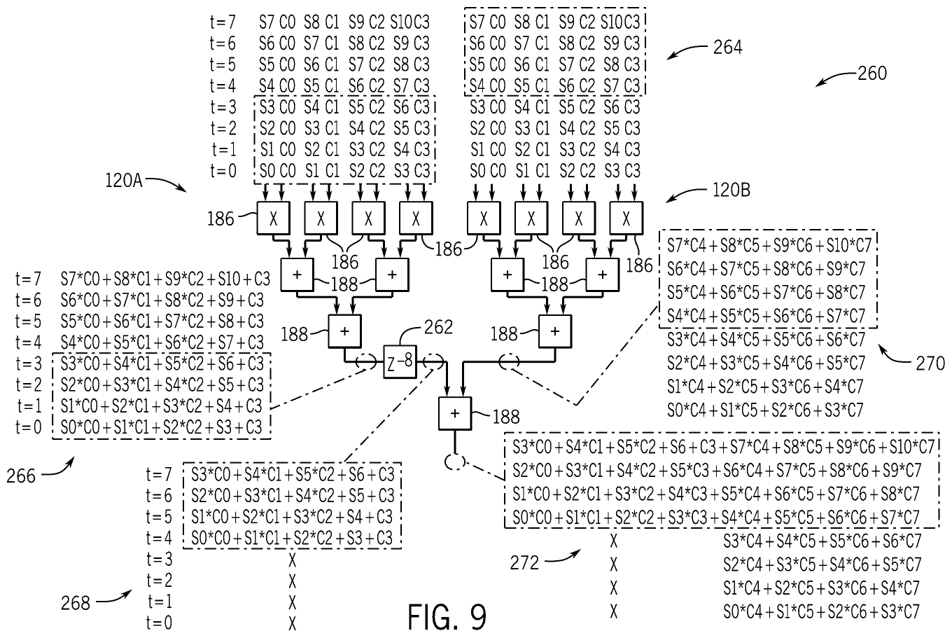

FIG. 9 is a dataflow diagram illustrating a dataflow through an 8-tap hybrid transposed FIR filter 260 implemented using two direct four-tap FIR filters collectively arranged in a transposed form. The 8-tap hybrid transposed FIR filter 260 of FIG. 9 may have the same structure as the 8-tap direct FIR filter 240 of FIG. 8. except for output delay circuitry 262 at the output of the first DSP block 120A. The 8-tap hybrid transposed FIR filter 260 of FIG. 9 ultimately produces the same results as the 8-tap direct FIR filter 240 of FIG. 8, except that the results are delayed by four cycles due to the output delay circuitry 262. Yet the 8-tap hybrid transposed FIR filter 260 of FIG. 9 may have a simpler input sequence 264. Indeed, the multipliers 186 of the DSP block 120A receive the exact same stream of input data as the multipliers 186 of the DSP block 120B, which may greatly simplify routing input data to the hybrid transposed FIR filter 260. For example, at time t=0, the first multiplier 186 of the DSP block 120A multiplies input data S0 by coefficient C0; at time t=1, the first multiplier 186 of the DSP block 120A multiplies input data S1 by coefficient C0; at time t=2, the first multiplier 186 of the DSP block 120A multiplies input data S2 by coefficient C0; and at time t=3, the first multiplier 186 of the DSP block 120A multiplies input data S3 by coefficient C0. Similarly, at time t=0, the first multiplier 186 of the DSP block 120B multiplies input data S0 by coefficient C4; at time t=1, the first multiplier 186 of the DSP block 120B multiplies input data S1 by coefficient C4; and so on. This means that at time t=4, the first multiplier 186 of the DSP block 120B multiplies input data S4 by coefficient C4; at time t=5, the first multiplier 186 of the DSP block 120B multiplies input data S5 by coefficient C4, and so on. In other words, the input schedule 264 is the same for cycles t4 through t7 for the DSP block 120B in the hybrid transposed FIR filter 260 of FIG. 9 as cycles t0 through t3 are for the input schedule 242 of the direct FIR filter 240 of FIG. 8.

The results of the DSP block 120A of the hybrid transposed FIR filter 260 of FIG. 9 are shown in a first intermediate sequence 266, which are delayed by four cycles to produce a delayed first intermediate sequence 268. The results of the DPS block 120B are shown in a second intermediate sequence 270. The delayed first intermediate sequence 268 and the second intermediate sequence 270 may be added together in an adder 188 (e.g., located in the second DSP block 120B or implemented in soft logic of programmable logic circuitry) to produce an output sequence 272. Note that cycles t4 through t7 of the output sequence 272 of FIG. 9 provide the same result as cycles t0 through t3 of the output sequence 248 of FIG. 8.

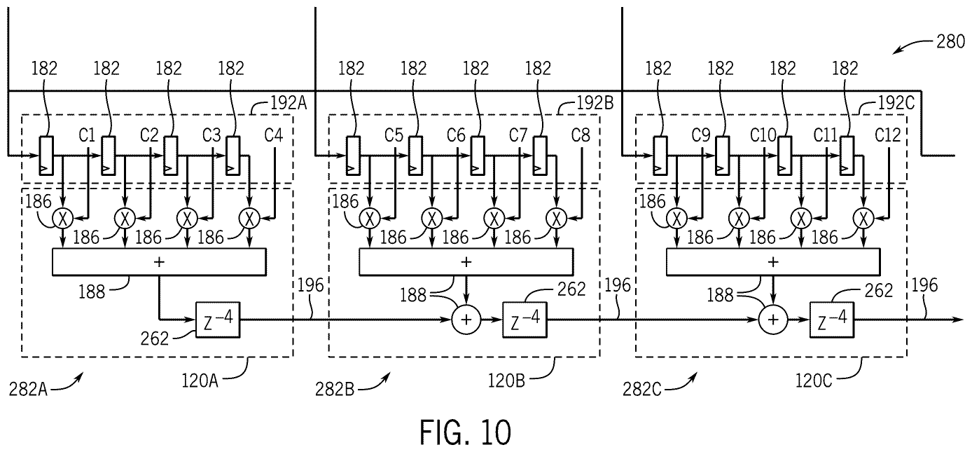

FIG. 10 illustrates one manner of implementing a hybrid transposed FIR filter 280 composed of separate direct FIR filters 282 formed using DSP blocks 120. The hybrid transposed FIR filter 280 implements a 12-tap filter using three four-tap direct FIR filters 282A, 282B, and 282C, but filters of different tap sizes may be formed using more or fewer FIR filters 282 with more or fewer DSP blocks 120. Moreover, the DSP blocks 120 in the example of FIG. 10 include four multipliers 186, but more or fewer multipliers 186 per DSP block 120 may be used. In the example of FIG. 10, the FIR filter 282A is formed using hardened circuitry of a DSP block 120A and an input delay chain 192A of registers 182, the FIR filter 282B is formed using hardened circuitry of a DSP block 120B and an input delay chain 192B of registers 182, and the FIR filter 282C is formed using hardened circuitry of a DSP block 120C and an input delay chain 192C of registers 182. The input delay chains 192A, 192B, and 192C may be implemented in soft logic of programmable logic circuitry or may be a component of the DSP blocks 120A, 120B, and 120C.

The direct FIR filters 282A, 282B, and 282C all receive the same input data, which is multiplied by coefficients c1, c2, c3, and c4 in the multipliers 186 of the DSP block 120A, by coefficients c5, c6, c7, and c8 in the multipliers 186 of the DSP block 120B, and by coefficients c9, c10, c11, and c12 in the multipliers 186 of the DSP block 120C. These products are added in respective adders 188. The result of the DSP block 120A is delayed using output delay circuitry 262 to delay the output by four cycles before it is added, in the DSP block 120B, to the result of the DSP block 120B. Likewise, the result of the DSP block 120B is delayed using comparable output delay circuitry 262 to delay the output by four cycles before it is added, in the DSP block 120C, to the result of the DSP block 120C. Note that, as in the hybrid transposed FIR filter 260 of FIG. 9, the direct FIR filters 282A, 282B, and 282C all receive the same input data, simplifying input routing. The output of the direct FIR filters 282A and 282B are delayed using output delay circuitry 262 to delay the output by four cycles. This produces results that are delayed but equivalent to a fully direct 12-tap FIR filter in the manner discussed above with reference to FIG. 9.

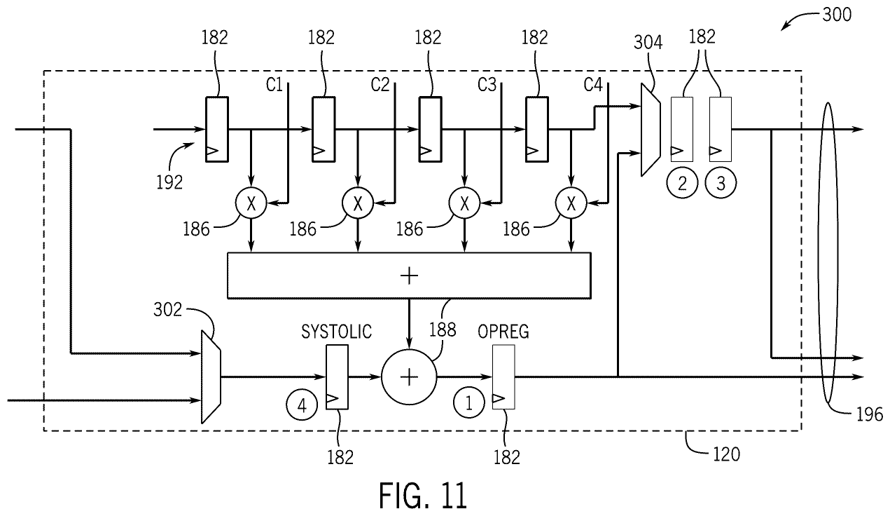

FIG. 11 illustrates one manner in which one DSP block 120 may be used to implement a direct FIR filter 300 that may be combined into a hybrid transposed FIR filter by applying additional output delay. In the direct FIR filter 300 of FIG. 11, the DSP block 120 includes four multipliers 186 that feed into adders 188 (e.g., which may be components of integer addition circuitry or floating-point addition circuitry of the DSP block 120). An input delay chain 192 of registers 182 may be integrated into the DSP block 120 or may be implemented in soft logic of programmable logic circuitry. The DSP block 120 may include multiplexers 302 and 304 that allow output data to be routed through additional registers 182 to provide sufficient delay to implement a hybrid transposed FIR filter. Here, there are four registers 182 in the input delay chain 192 of registers 182. Accordingly, the DSP block 120 may enable the output result to be routed through four registers 182 before being added into the output result of another DSP block 120 (e.g., via a direct path 196). These include an output register (“opreg”) register 182 (labeled “1”) and two registers 182 accessible through the multiplexer 304 (labeled “2” and “3”), and a systolic input register (“systolic”) register 182 (labeled “4”). Note that, in a hybrid transposed FIR filter implemented using multiple DSP blocks 120, the fourth register 182 may be the systolic input register (“systolic”) register 182 in the next DSP block 120 (e.g., three delay registers 182 in a first DSP block 120 and a fourth delay register 182 in a second DSP block 120, for a total of four delay registers 182). For purposes of the output delay, it does not matter where the registers 182 are physically located, and it does not matter if they are found in two different DSP blocks 120. In other embodiments, any suitable number of registers equal to the number of filter taps (e.g., input delay chain 192 registers 182, multipliers 186) may be used. For example, in a five-tap implementation where the input delay chain 192 instead uses five registers 182 to provide input data entering five multipliers 186, the DSP block 120 may include five delay registers in total between stages.

The balancing registers 182 labeled 1, 2, 3, and 4 may be repurposed registers 182 that are present in the DSP block 120 for other purposes. Indeed, registers 182 are expensive, and it may not be economical to simply add four registers 182. But there may be additional balancing registers 182 in the input data chain 192 of the DSP block 120, which are not used to chain input data from one DSP block 120 to another in the hybrid transposed form. These can be repurposed to add two delay registers 182 (labeled “2” and “3”).

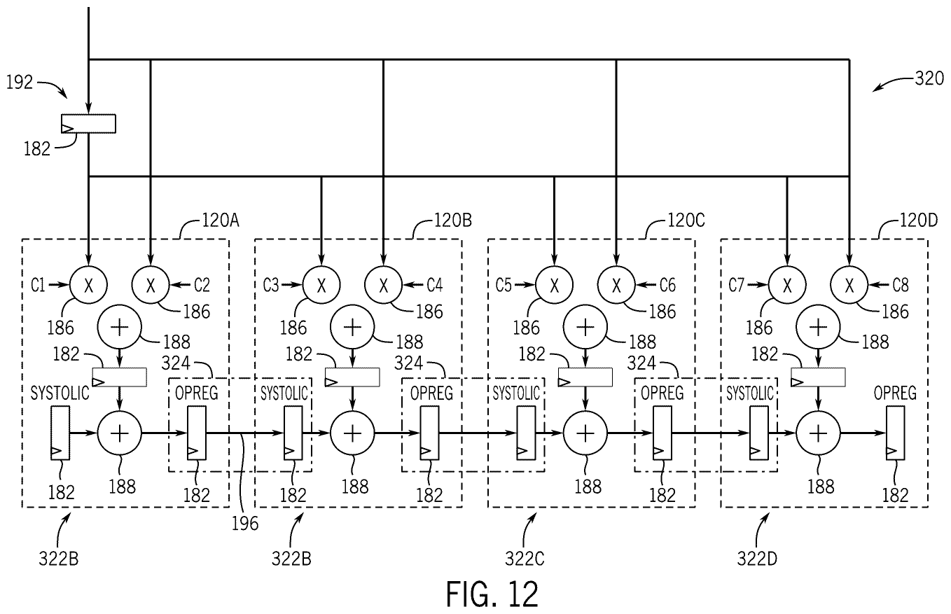

Some DSP blocks 120 may have a total of two multipliers 186 per DSP block 120. FIG. 12 illustrates a hybrid transposed FIR filter 320 composed of two-tap direct FIR filters 322 that are connected together in a transposed form (e.g., a FIR filter 322A using a DSP block 120A, a FIR filter 322B using a DSP block 120B, a FIR filter 322C using a DSP block 120C, and a FIR filter 322D using a DSP block 120D). This structure can be used with an external delay when an internal data delay is not available or unwanted. Moreover, the delay between DSP blocks 120 may be provided by registers 182 found in the DSP blocks 120. Each two-tap direct FIR filter 322 may receive the same input data from a common input data chain 192 having only one register 182. The input data is multiplied by a respective coefficient (e.g., c1, c2, . . . , c8) in multipliers 186. The products of the multipliers 186 are added in an adder 188 and delayed by one cycle in a register 182. The result from one FIR filter 322 may be output via an output register (“opreg”) register 182 and provided to an adjacent FIR filter 322 via a direct path 196 and stored in an input systolic register (“systolic”) register 182. An output delay 324 due to the output register (“opreg”) register 182 of a first DSP block 120 (e.g., the DSP block 120A) and the input systolic register (“systolic”) register 182 of a second DSP block 120 (e.g., the DSP block 120B) may provide two cycles of delay, the same amount of delay as the number of taps of each direct FIR filter 322. This allows the hybrid transposed FIR filter 320 to produce the same (but delayed) results as a fully direct FIR filter but with simpler input data routing.

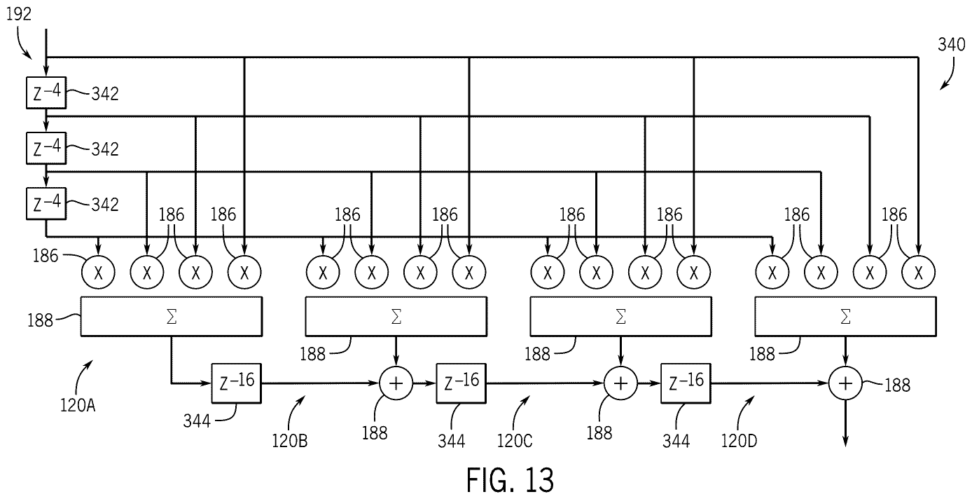

FIG. 13 illustrates a multi-channel hybrid transposed FIR filter 340. The multi-channel hybrid transposed FIR filter 340 may be implemented using several DSP blocks 120 (e.g., here, DSP blocks 120A, 120B, 120C, and 120D). In this example, each DSP block 120 implements a direct four-tap FIR filter using four multipliers 186 that multiply input data by different respective coefficients c1, c2, . . . , c15. The products of the four multipliers 186 of each DSP block 120 are added in adders 188. In the example of FIG. 13, there are four channels of input data. As such, a common input delay chain 192 includes three four-cycle input delays 342. This effectively multiplexes the application of the input data into the DSP blocks 120 based on the channel. The results of each DSP block 120 may be further delayed using output delay circuitry 344 based on the number of taps implemented by each DSP block 120 and the number of channels. In this example, each DSP block 120 implements a direct FIR filter with four taps, applied to four channels, so a delay of 16 cycles is used (e.g., 4*4=16).

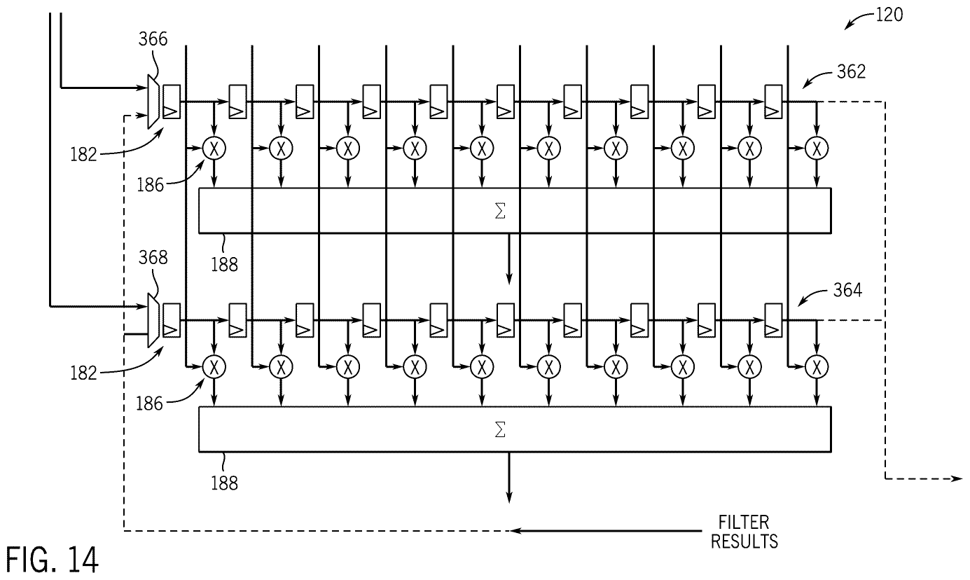

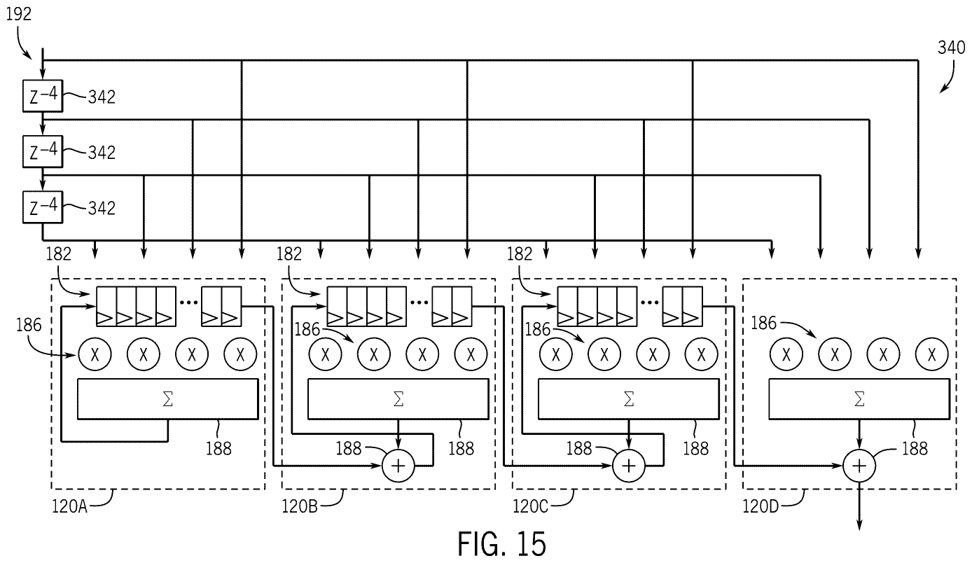

As mentioned above, registers 182 are expensive to add. Therefore, it may be more efficient to repurpose other registers 182 that may have been originally included in a DSP block 120 for other purposes. For instance, many DSP blocks 120 include tensor circuits to perform lower-precision tensor operations. One example is shown in FIG. 14, in which a DSP block 120 includes a first tensor circuit 362 and a second tensor circuit 364. The tensor circuits 362, 364 include an array of multipliers 186 (e.g., which may be of lower precision than the multipliers 186 used to compose the FIR filter of FIG. 13) and adders 188. But the tensor circuits 362, 364 also include arrays of registers 182 that normally have a function that is not to provide balancing delay between elements. These arrays of registers 182 of the tensor circuits 362, 364 may be repurposed to provide a suitable delay like. In the example of FIG. 13, the output of filter results may be selectively input into the array of registers 182 of the tensor circuits 362, 364 using multiplexers 366 or 368. The array of registers 182 of the tensor circuits 362, 364 may be selectably bypassable to enable a selectable amount of delay and the multipliers 186 and adders 188 of the tensor circuits 362, 364 may not be used. In this way, the array of registers 182 of the tensor circuitry 362, 364 may be made to behave like other registers 182 used for balancing delay. FIG. 15 provides an example of the multi-channel hybrid transposed FIR filter 340 where the filter results of the DSP blocks 120 are routed through the array of registers 182 of the tensor circuits 362, 364 to provide output delay.

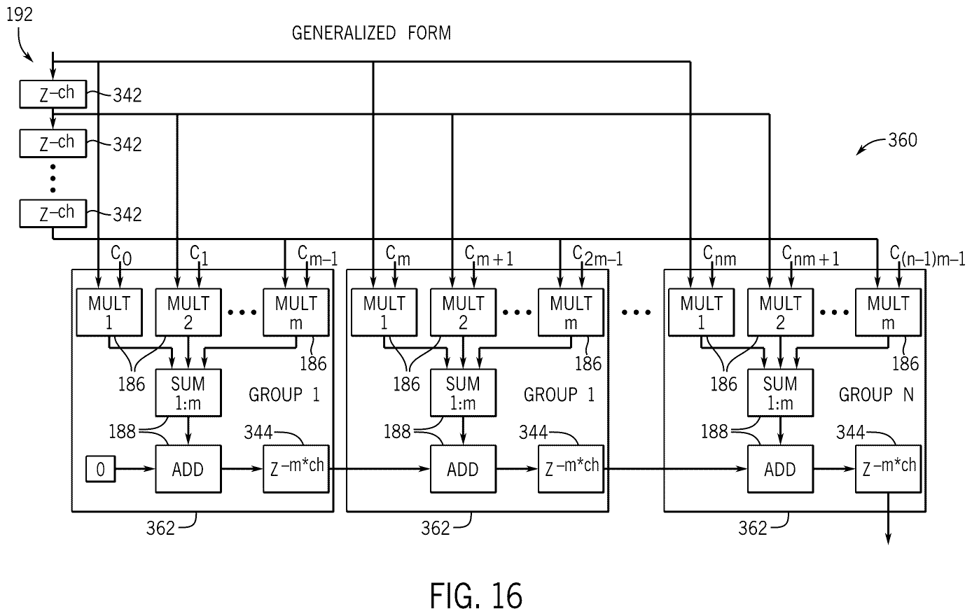

FIG. 16 provides a generalized form of a multi-channel hybrid FIR filter 360 that may be implemented. The multi-channel hybrid FIR filter 360 may include any suitable number “n” of direct FIR filter groups 362 (e.g., group 1, group 2, . . . , group n). Each direct FIR filter group 362 may include “m” multipliers 186 and adder 188 circuitry to sum the results of the multipliers 186 and the result from the previous group 362. An input delay chain 192 may include a number m-1 of multi-cycle input delays 342 that apply ch cycles of delay, where “ch” represents the number of interleaved channels in the input signal. Output delay circuitry 344 of each group may provide m*ch cycles of delay.

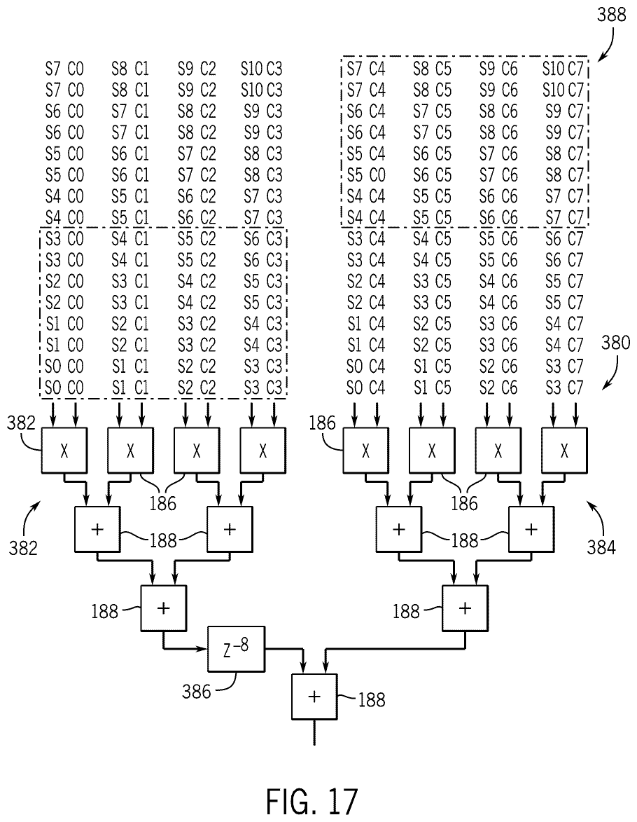

FIGS. 17-19 describe a dataflow through a multi-channel hybrid transposed FIR filter 380 that processes two interleaved channels of input data through two direct FIR filters 382 and 384 (e.g. one formed based on a DSP block 120A and one formed based on a DSP block 120B). The multi-channel hybrid transposed FIR filter 380 of FIGS. 17-19 may have an architecture based on the hybrid transposed FIR filter 260 shown in FIG. 9, except that output delay circuitry 386 is sized to accommodate the two channels of input data. Here, since there are two channels of input data and four multipliers 186 per direct FIR filter 382 and 384, the output delay circuitry 382 provides eight cycles of delay.

FIG. 17 illustrates an input sequence 388 of input data. The data input into both direct FIR filters 382 and 384 may be the same. For example, at time t=0, the first multiplier 186 of the DSP block 120A multiplies input data S0 of the first channel by coefficient C0; at time t=1, the first multiplier 186 of the DSP block 120A multiplies input data S0 of the second channel by coefficient C0; at time t=2, the first multiplier 186 of the DSP block 120A multiplies input data S1 of the first channel by coefficient C0; and at time t=3, the first multiplier 186 of the DSP block 120A multiplies input data S1 of the second channel by coefficient C0, and so on. Similarly, at time t=0, the first multiplier 186 of the DSP block 120B multiplies input data S0 of the first input channel by coefficient C4; at time t=1, the first multiplier 186 of the DSP block 120B multiplies input data S0 of the second channel by coefficient C4; at time t=2, the first multiplier 186 of the DSP block 120B multiplies input data S1 of the first channel by coefficient C0; and at time t=3, the first multiplier 186 of the DSP block 120B multiplies input data S1 of the second channel by coefficient C0, and so on. This means that beginning at time t=8, the first multiplier 186 of the DSP block 120B multiplies input data S4 of the first channel by coefficient C4; at time t=5, the first multiplier 186 of the DSP block 120B multiplies input data S4 of the second channel by coefficient C4, and so on. In other words, the input schedule 388 is simpler than would be applied to a fully direct form of FIR filter since each direct FIR filter 382, 384 receive the same inputs, but ultimately the same computations occur (but delayed) in the multi-channel hybrid transposed FIR filter 380.

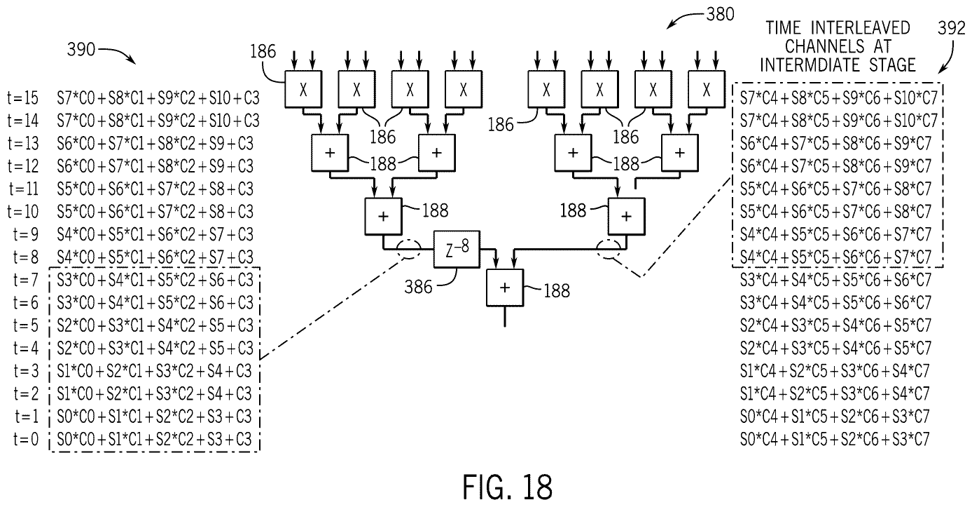

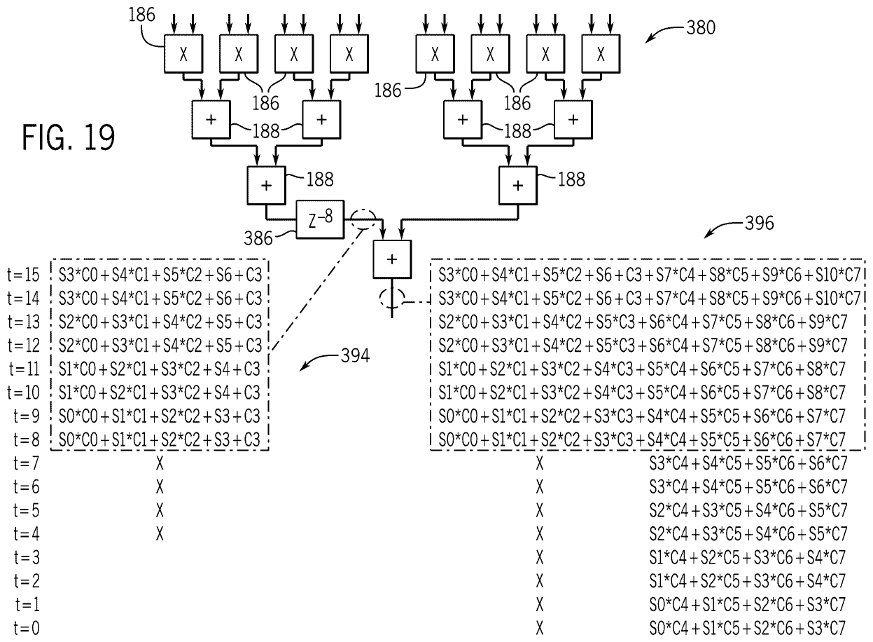

Intermediate sequences 390 and 392 are shown in FIG. 18 as the partial results from the direct FIR filters 382 and 384, respectively. As shown in FIG. 19, the partial result from the intermediate sequence 390 may be delayed by the output delay circuitry 386 to produce a delayed intermediate sequence 394. When the delayed intermediate sequence 394 is added to the intermediate sequence 392, an output sequence 396 is obtained. The output sequence 396 produces filter results from the multi-channel hybrid transposed FIR filter 380 after an amount of delay corresponding to the output delay circuitry 388.

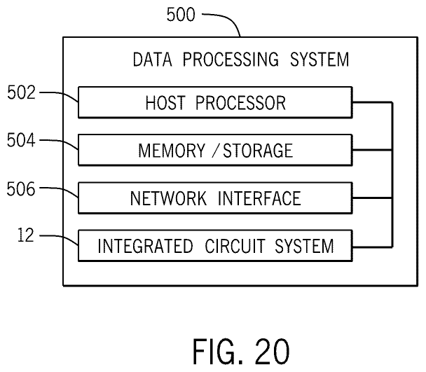

The circuits discussed above may be implemented on the integrated circuit system 12, which may be a component included in a data processing system, such as a data processing system 500, shown in FIG. 20. The data processing system 500 may include the integrated circuit system 12 (e.g., a programmable logic device, an application specific integrated circuit (ASIC)), a host processor 502, memory and/or storage circuitry 504, and a network interface 506. The data processing system 500 may include more or fewer components (e.g., electronic display, user interface structures, application specific integrated circuits (ASICs)). Moreover, any of the circuit components depicted in FIG. 20 may include the integrated circuit system 12. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. An integrated circuit device comprising:
programmable logic circuitry; and
a digital signal processing (DSP) block embedded in the programmable logic circuitry having a plurality of hardened multipliers and registers and being configurable to implement a transposed finite impulse response (FIR) filter.

EXAMPLE EMBODIMENT 2. The integrated circuit device of example embodiment 1, wherein the transposed FIR filter comprises a transposed sparse FIR filter.

EXAMPLE EMBODIMENT 3. The integrated circuit device of example embodiment 2, wherein the transposed sparse FIR filter comprises a transposed halfband FIR filter.

EXAMPLE EMBODIMENT 4. The integrated circuit device of example embodiment 2, wherein the DSP block comprises a number of registers configurable to provide additional output delay corresponding to multiply-by-0 operations of the transposed sparse FIR filter.

EXAMPLE EMBODIMENT 5. The integrated circuit device of example embodiment 1, comprising a plurality of the DSP blocks, wherein the transposed FIR filter spans the plurality of the DSP blocks.

EXAMPLE EMBODIMENT 6. The integrated circuit device of example embodiment 5, wherein the transposed FIR filter comprises a hybrid transposed FIR filter formed from a plurality of non-transposed FIR filters having outputs delayed using registers within the plurality of the DSP blocks.

EXAMPLE EMBODIMENT 7. The integrated circuit device of example embodiment 6, wherein the registers within the plurality of the DSP blocks comprise registers repurposed from an input delay chain.

EXAMPLE EMBODIMENT 8. The integrated circuit device of example embodiment 6, wherein the registers within the plurality of the DSP blocks comprise registers of a tensor circuit.

EXAMPLE EMBODIMENT 9. The integrated circuit device of example embodiment 5, wherein the transposed FIR filter comprises a hybrid transposed FIR filter comprising:
a first DSP block of the plurality of the DSP blocks configurable to produce a first intermediate sequence and delay the first intermediate sequence by a number of cycles based on a number of the plurality of multipliers of the first DSP block used to produce the first intermediate sequence to obtain a first delayed result;
a second DSP block of the plurality of the DSP blocks configurable to produce a second intermediate sequence; and
adder circuitry to add the second intermediate sequence to the delayed first intermediate sequence.

EXAMPLE EMBODIMENT 10. The integrated circuit device of example embodiment 5, wherein the transposed FIR filter comprises a multi-channel hybrid transposed FIR filter formed from a plurality of non-transposed FIR filters having outputs delayed using registers within the plurality of the DSP blocks.

EXAMPLE EMBODIMENT 11. Hybrid transposed finite impulse response (FIR) filter circuitry comprising:
a first direct multi-tap FIR filter circuit to produce a first interim result;
output delay circuitry to delay the first interim result based on a number of taps in the first direct multi-tap FIR filter to produce a delayed first interim result;
a second direct multi-tap FIR filter circuit to produce a second interim result; and
addition circuitry to add the delayed first interim result to the second interim result to produce a hybrid transposed FIR filter result.

EXAMPLE EMBODIMENT 12. The hybrid transposed FIR filter circuitry of example embodiment 11, wherein the first direct multi-tap FIR filter circuit comprises at least two taps.

EXAMPLE EMBODIMENT 13. The hybrid transposed FIR filter circuitry of example embodiment 11, wherein the first direct multi-tap FIR filter circuit comprises at least four taps.

EXAMPLE EMBODIMENT 14. The hybrid transposed FIR filter circuitry of example embodiment 11, wherein the output delay circuitry delays the first interim result by an integer multiple of the number of taps in the first direct multi-tap FIR filter.

EXAMPLE EMBODIMENT 15. The hybrid transposed FIR filter circuitry of example embodiment 11, comprising an input delay chain to provide a multi-channel input signal delayed based on a number of channels of the multi-channel input signal, wherein the output delay circuitry delays the first interim result based on the number of taps in the first direct multi-tap FIR filter and the number of channels of the multi-channel input signal.

EXAMPLE EMBODIMENT 16. The hybrid transposed FIR filter circuitry of example embodiment 11, wherein the first direct multi-tap FIR filter circuit is implemented using a first digital signal processing (DSP) block of a programmable logic device and the second direct multi-tap FIR filter circuit is implemented using a second DSP block of the programmable logic device.

EXAMPLE EMBODIMENT 17. The hybrid transposed FIR filter circuitry of example embodiment 16, wherein the output delay circuitry is implemented using registers in the first DSP block and the second DSP block.

EXAMPLE EMBODIMENT 18. The hybrid transposed FIR filter circuitry of example embodiment 16, wherein the addition circuitry is implemented in the second DSP block.

EXAMPLE EMBODIMENT 19. An article of manufacture comprising one or more tangible, non-transitory, machine-readable media that, when executed by a data processing system, generates a system design for a programmable logic device that comprises a configuration of an embedded digital signal processing (DSP) block comprising:
a first hardened multiplier circuit of the DSP block configured to multiply a first coefficient and a stream of input data to produce a first product;
a second hardened multiplier circuit of the DSP block configured to multiply a second coefficient and the stream of input data to produce a second product; and
one or more registers of the DSP block configured to provide delay to enable the DSP block to implement a transposed finite impulse response (FIR) filter.

EXAMPLE EMBODIMENT 20. The article of manufacture of example embodiment 19, wherein the transposed FIR filter comprises a transposed sparse FIR filter.

What is claimed is:

1. An integrated circuit device comprising:
programmable logic circuitry; and
a digital signal processing (DSP) block embedded in the programmable logic circuitry having a plurality of hardened multipliers and registers and being configurable to implement a transposed finite impulse response (FIR) filter.

2. The integrated circuit device of claim 1, wherein the registers of the DSP block are configurable to be arranged to enable a portion of the transposed FIR filter implemented by the DSP block to use a single reduction structure.

3. The integrated circuit device of claim 1, wherein the transposed FIR filter comprises a transposed sparse FIR filter.

4. The integrated circuit device of claim 3, wherein the DSP block comprises a number of registers configurable to provide additional output delay corresponding to multiply-by-0 operations of the transposed sparse FIR filter.

5. The integrated circuit device of claim 1, comprising a plurality of the DSP blocks, wherein the transposed FIR filter spans the plurality of the DSP blocks.

6. The integrated circuit device of claim 5, wherein the transposed FIR filter comprises a hybrid transposed FIR filter formed from a plurality of non-transposed FIR filters having outputs delayed using registers within the plurality of the DSP blocks.

7. The integrated circuit device of claim 6, wherein the registers within the plurality of the DSP blocks comprise registers repurposed from an input delay chain.

8. The integrated circuit device of claim 6, wherein the registers within the plurality of the DSP blocks comprise registers of a tensor circuit.

9. The integrated circuit device of claim 5, wherein the transposed FIR filter comprises a hybrid transposed FIR filter comprising:
a first DSP block of the plurality of the DSP blocks configurable to produce a first intermediate sequence and delay the first intermediate sequence by a number of cycles based on a number of the plurality of multipliers of the first DSP block used to produce the first intermediate sequence to obtain a first delayed result;
a second DSP block of the plurality of the DSP blocks configurable to produce a second intermediate sequence; and
adder circuitry to add the second intermediate sequence to the delayed first intermediate sequence.

10. The integrated circuit device of claim 5, wherein the transposed FIR filter comprises a multi-channel hybrid transposed FIR filter formed from a plurality of non-transposed FIR filters having outputs delayed using registers within the plurality of the DSP blocks.

11. Hybrid transposed finite impulse response (FIR) filter circuitry comprising:
a first direct multi-tap FIR filter circuit to produce a first interim result;
output delay circuitry to delay the first interim result based on a number of taps in the first direct multi-tap FIR filter to produce a delayed first interim result;
a second direct multi-tap FIR filter circuit to produce a second interim result; and
addition circuitry to add the delayed first interim result to the second interim result to produce a hybrid transposed FIR filter result.

12. The hybrid transposed FIR filter circuitry of claim 11, wherein the first direct multi-tap FIR filter circuit comprises at least two taps.

13. The hybrid transposed FIR filter circuitry of claim 11, wherein the first direct multi-tap FIR filter circuit comprises at least four taps.

14. The hybrid transposed FIR filter circuitry of claim 11, wherein the output delay circuitry delays the first interim result by an integer multiple of the number of taps in the first direct multi-tap FIR filter.

15. The hybrid transposed FIR filter circuitry of claim 11, comprising an input delay chain to provide a multi-channel input signal delayed based on a number of channels of the multi-channel input signal, wherein the output delay circuitry delays the first interim result based on the number of taps in the first direct multi-tap FIR filter and the number of channels of the multi-channel input signal.

16. The hybrid transposed FIR filter circuitry of claim 11, wherein the first direct multi-tap FIR filter circuit is implemented using a first digital signal processing (DSP) block of a programmable logic device and the second direct multi-tap FIR filter circuit is implemented using a second DSP block of the programmable logic device.

17. The hybrid transposed FIR filter circuitry of claim 16, wherein the output delay circuitry is implemented using registers in the first DSP block and the second DSP block.

18. The hybrid transposed FIR filter circuitry of claim 16, wherein the addition circuitry is implemented in the second DSP block.

19. An article of manufacture comprising one or more tangible, non-transitory, machine-readable media that, when executed by a data processing system, generates a system design for a programmable logic device that comprises a configuration of an embedded digital signal processing (DSP) block comprising:
a first hardened multiplier circuit of the DSP block configured to multiply a first coefficient and a stream of input data to produce a first product;
a second hardened multiplier circuit of the DSP block configured to multiply a second coefficient and the stream of input data to produce a second product; and
one or more registers of the DSP block configured to provide delay to enable the DSP block to implement a transposed finite impulse response (FIR) filter.

20. The article of manufacture of claim 19, wherein the transposed FIR filter comprises a transposed sparse FIR filter.
